(19) United States
(12) Patent Application Publication
(10) Pub. No.: US 2025/0002329 A1
(43) Pub. Date: Jan. 2, 2025

(54) MEMS SENSOR

(71) Applicant: ROHM CO., LTD., Kyoto (JP)

(72) Inventor: Masahiro SAKURAGI, Kyoto-shi (JP)

(73) Assignee: ROHM CO., LTD., Kyoto (JP)

(21) Appl. No.: 18/884,073

(22) Filed: Sep. 12, 2024

Related U.S. Application Data
(63) Continuation of application No. PCT/JP2022/046939, filed on Dec. 20, 2022.

(30) Foreign Application Priority Data
Mar. 16, 2022 (JP) 2022-041601

(51) Int. Cl. B81B 7/00; G01L 1/18

(52) U.S. Cl. CPC B81B 7/0006; G01L 1/18; B81B 2201/0264; B81B 2203/0127; B81B 2203/0315

(57) ABSTRACT

AMEMS sensor includes a semiconductor substrate, a sensor unit formed on the semiconductor substrate, a pad unit formed on the semiconductor substrate, and a connection wiring formed on the semiconductor substrate and connecting the sensor unit and the pad unit. The connection wiring is a semiconductor wiring formed from a semiconductor material.

### TECHNICAL FIELD

The present disclosure relates to a MEMS sensor.

### BACKGROUND ART

A micro electro mechanical system (MEMS) sensor manufactured using a semiconductor microfabrication technique is known. As a MEMS sensor, JP 2016-17747A discloses a piezoresistive pressure sensor. The piezoresistive pressure sensor includes a diaphragm formed on a semiconductor substrate and a plurality of piezoresistive elements formed on the diaphragm, and is configured to detect pressure by detecting deflection of the diaphragm due to a pressure difference acting on both sides of the diaphragm as a resistance value change of the piezoresistive element.

### BRIEF DESCRIPTION OF DRAWINGS

FIG. 1 is a plan view of a MEMS sensor according to a first embodiment of the present disclosure;

FIG. 2 is a cross-sectional view of the MEMS sensor taken along line II-II of FIG. 1;

FIG. 3 is a cross-sectional view of the MEMS sensor taken along line III-III of FIG. 1;

FIG. 4 is a plan view of the MEMS sensor in which a sensor unit and a pad unit are connected by a metal wiring;

FIG. 5 is a cross-sectional view of the MEMS sensor taken along line V-V of FIG. 4;

FIG. 6 is a plan view illustrating a variation of the MEMS sensor according to the first embodiment;

FIG. 7 is a plan view illustrating another variation of the MEMS sensor according to the first embodiment;

FIG. 8 is a plan view of the MEMS sensor according to a second embodiment of the present disclosure;

FIG. 9 is a cross-sectional view of the MEMS sensor taken along line IX-IX in FIG. 8; and

FIG. 10 is a plan view of the MEMS sensor according to a third embodiment of the present disclosure.

### DETAILED DESCRIPTION

Hereinafter, an embodiment of the present disclosure will be described with reference to the drawings.

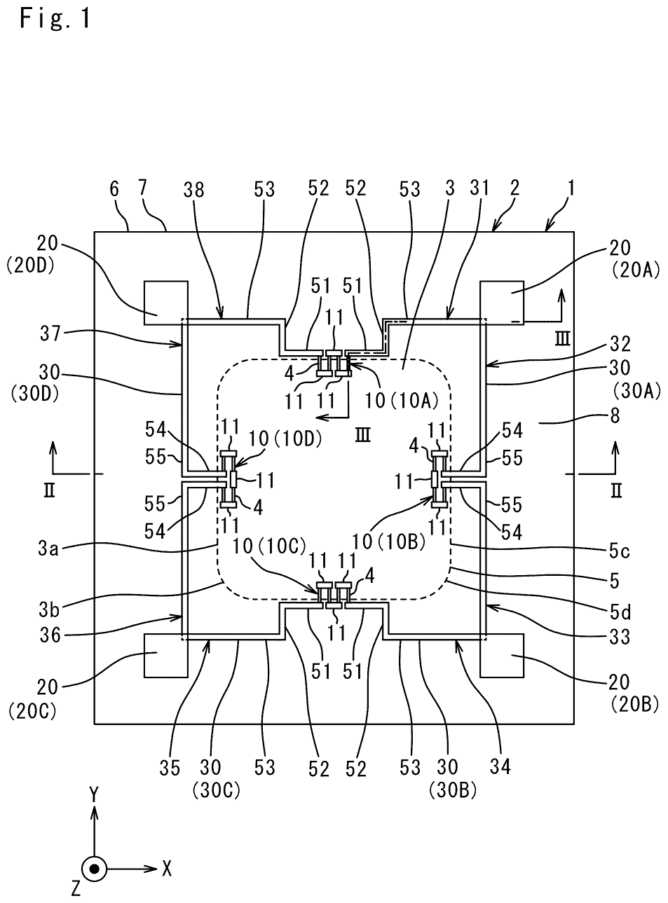

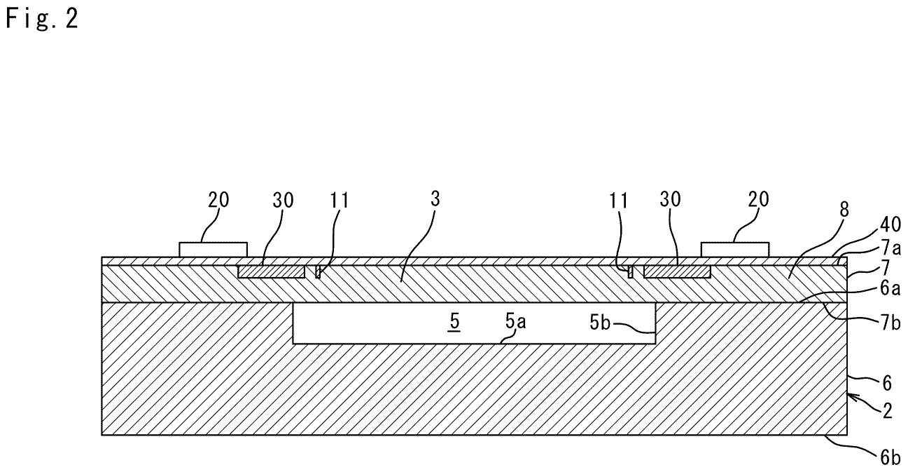

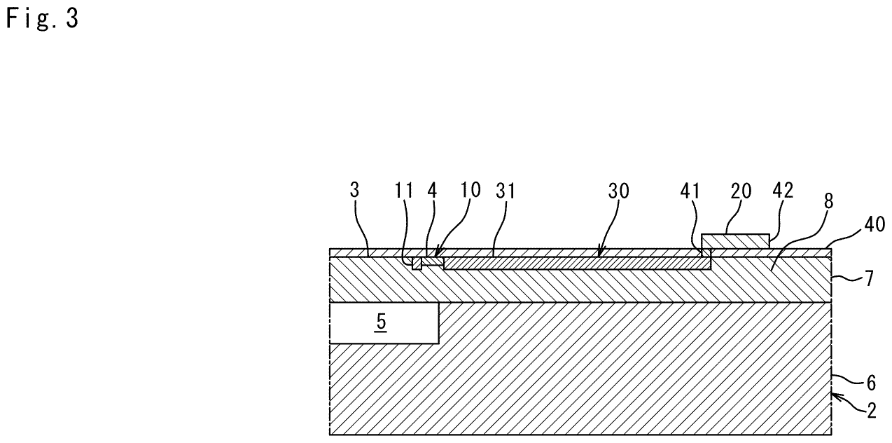

FIG. 1 is a plan view of a MEMS sensor according to a first embodiment of the present disclosure. FIG. 2 is a cross-sectional view of the MEMS sensor taken along line II-II of FIG. 1. FIG. 3 is a cross-sectional view of the MEMS sensor taken along line III-III of FIG. 1. As illustrated in FIGS. 1 to 3, a MEMS sensor 1 according to an embodiment of the present disclosure is a piezoresistive pressure sensor in which a diaphragm 3 is formed on a substrate 2 and a piezoresistive element is formed as a sensor element 4 on the diaphragm 3. The MEMS sensor 1 is manufactured by processing the substrate 2 using a semiconductor microfabrication technique.

Hereinafter, a predetermined direction along a surface of the substrate 2 is defined as an X direction, a direction orthogonal to the X direction is defined as a Y direction, and a thickness direction of the substrate 2 orthogonal to the X direction and the Y direction is defined as a Z direction. FIG. 1 illustrates the substrate 2 viewed from the upper side in the Z direction which is the front surface side of the substrate 2.

On the substrate 2, a sensor unit 10 each having a piezoresistive element 4, a pad unit 20 each connected to an external electronic component, and a connection wiring 30 that connects the sensor unit 10 and the pad unit 20 and connects between the sensor units 10 are formed. The sensor unit 10 is formed on the diaphragm 3 arranged on a cavity 5 formed in the substrate 2.

As illustrated in FIGS. 2 and 3, the substrate 2 includes a first substrate 6 having a first main surface 6a as a front surface and a second main surface 6b as a back surface on the opposite side to the first main surface 6a, and a second substrate 7 having a first main surface 7a as a front surface and a second main surface 7b as a back surface on the opposite side to the first main surface 7a. The substrate 2 is formed by joining the first main surface 6a of the first substrate 6 and the second main surface 7b of the second substrate 7. The front surface of the substrate 2 is formed by the first main surface 7a of the second substrate 7, and the back surface of the substrate 2 is formed by the second main surface 6b of the first substrate 6.

As illustrated in FIG. 1, the first substrate 6 and the second substrate 7 are formed in the same shape in plan view, and are formed in a rectangular shape having two sides extending parallel to the X direction and two sides extending parallel to the Y direction. As the first substrate 6 and the second substrate 7, an n-type semiconductor substrate doped with an n-type impurity such as phosphorus to impart conductivity is used.

As illustrated in FIG. 2, the first substrate 6 has the cavity 5 recessed from the first main surface 6a toward the second main surface. The cavity 5 is formed to be recessed in a substantially rectangular parallelepiped shape in a thickness direction of the first substrate 6, and has a bottom wall portion 5a and a side wall portion 5b. As illustrated in FIG. 1, the cavity 5 is formed in a substantially quadrangular shape in plan view, and includes four side portions 5c and four corner portions 5d, and each of the corner portions 5d is formed in a curved round shape.

The second substrate 7 includes the diaphragm 3 arranged on the cavity 5 and a fixing portion 8 joined and fixed to the second substrate 7, and the fixing portion 8 is provided around the diaphragm 3. The diaphragm 3 is deformed and deflected by a pressure difference acting on both sides of the diaphragm. The cavity 5 is sealed by the diaphragm 3 by joining of the first substrate 6 and the second substrate 7, and is formed in vacuum in the MEMS sensor 1.

As illustrated in FIG. 1, the diaphragm 3 is formed in a substantially quadrangular shape in the same shape as the cavity 5 in plan view. The diaphragm 3 includes four side portions 3a and four corner portions 3b, and the corner portions 3b are each formed in a curved round shape. The piezoresistive element 4 constituting the sensor unit 10 is formed on the diaphragm 3.

The MEMS sensor 1 includes a plurality of the sensor units 10, a plurality of pad units 20, and a plurality of the connection wirings 30, and a plurality of the connection wirings 30 are formed to connect the sensor unit 10 and the pad unit 20 and to connect the sensor units 10. The MEMS sensor 1 includes four of the sensor units 10 and four of the pad units 20, and the sensor unit 10, the pad unit 20, and the connection wiring 30 are formed on the front surface side of the substrate 2.

Each of a plurality of the sensor units 10 includes the piezoresistive element 4. The piezoresistive element 4 is formed as a diffusion resistor by doping a surface of the substrate 2 with a p-type impurity such as boron so as to have impurity concentration of, for example, about 10¹⁹/cm³. The piezoresistive element 4 has predetermined thickness in a thickness direction of the substrate 2 and is formed in a rectangular shape in plan view. The piezoresistive element 4 is arranged such that its longitudinal direction extends in the Y direction.

A first sensor unit 10A is arranged on the side portion 3a on one side in the Y direction of the diaphragm 3, a second sensor unit 10B is arranged on the side portion 3a on one side in the X direction of the diaphragm 3, a third sensor unit 10C is arranged on the side portion 3a on another side in the Y direction of the diaphragm 3, and a fourth sensor unit 10D is arranged on the side portion 3a on another side in the X direction of the diaphragm 3.

The piezoresistive elements 4 of the first sensor unit 10A and the third sensor unit 10C have their longitudinal directions arranged to extend in the Y direction and be orthogonal to the side portion 3a of the diaphragm 3. The piezoresistive elements 4 of the first sensor unit 10A and the third sensor unit 10C are arranged in a manner extending to the diaphragm 3 and the fixing portion 8.

Each of the first sensor unit 10A and the third sensor unit 10C includes four of the piezoresistive elements 4, and four of the piezoresistive elements 4 are arranged to be separated from each other in the X direction. Four of the piezoresistive elements 4 are connected via a relay wiring 11 connecting the piezoresistive elements 4, and the relay wiring 11 connects four of the piezoresistive elements 4 in series.

The piezoresistive elements 4 of the second sensor unit 10B and the fourth sensor unit 10D have their longitudinal directions arranged to extend in the Y direction and be in parallel to the side portion 3a of the diaphragm 3. The piezoresistive elements 4 of the second sensor unit 10B and the fourth sensor unit 10D are arranged only on the diaphragm 3.

Each of the second sensor unit 10B and the fourth sensor unit 10D includes four of the piezoresistive elements 4, and four of the piezoresistive elements 4 are provided such that two sets of two of the piezoresistive elements 4 arranged to be separated in the X direction are separated in the Y direction. Four of the piezoresistive elements 4 are connected via a relay wiring 11 connecting the piezoresistive elements 4, and the relay wiring 11 connects four of the piezoresistive elements 4 in series.

Each of the relay wirings 11 is formed in a rectangular shape in plan view, and is formed as a diffusion wiring by doping a surface of the substrate 2 with a p-type impurity such as boron so as to have high concentration, for example, impurity concentration of about 10²⁰/cm³. The relay wiring 11 is doped with a p-type impurity at higher concentration than that of the piezoresistive element 4.

Each of a plurality of the pad units 20 has predetermined thickness in a thickness direction of the substrate 2, and is formed in a quadrangular shape having two sides extending parallel to the X direction and two sides extending parallel to the Y direction in plan view. The pad unit 20 is provided outside four of the corner portions 3b of the diaphragm 3 on the front surface of the substrate 2.

A first pad unit 20A is arranged further on one side in the Y direction and on one side in the X direction than the diaphragm 3, a second pad unit 20B is arranged further on another side in the Y direction and on one side in the X direction than the diaphragm 3, a third pad unit 20C is arranged further on another side in the Y direction and on another side in the X direction than the diaphragm 3, and the fourth pad unit 20D is arranged further on one side in the Y direction and on another side in the X direction than the diaphragm 3.

The pad unit 20 is connected to an external electronic component or the like using a bonding wire. As illustrated in FIG. 3, the pad unit 20 is formed from an aluminum layer formed on an insulating film 40 formed on the front surface of the substrate 2.

As illustrated in FIG. 1, the connection wiring 30 includes a first connection wiring 30A that connects the first sensor unit 10A and the second sensor unit 10B and is connected to the first pad unit 20A, a second connection wiring 30B that connects the second sensor unit 10B and the third sensor unit 10C and is connected to the second pad unit 20B, a third connection wiring 30C that connects the third sensor unit 10C and the fourth sensor unit 10D and is connected to the third pad unit 20C, and a fourth connection wiring 30D that connects the fourth sensor unit 10D and the first sensor unit 10A and is connected to the fourth pad unit 20D.

A plurality of the connection wirings 30A, 30B, 30C, and 30D bridge connect the piezoresistive elements 4 of the first sensor unit 10A to the fourth sensor unit 10D to form a bridge circuit. The first pad unit 20A, the second pad unit 20B, the third pad unit 20C, and the fourth pad unit 20D function as a negative-side output pad unit, a grounding pad unit, a positive-side output pad unit, and a voltage application pad unit, respectively. The first connection wiring 30A, the second connection wiring 30B, the third connection wiring 30C, and the fourth connection wiring 30D function as a negative-side output connection wiring, a grounding connection wiring, a positive-side output connection wiring, and a voltage application connection wiring, respectively.

The connection wiring 30 has predetermined thickness in a thickness direction of the substrate 2 and is formed to have predetermined width smaller than that of the pad unit 20 in plan view. The connection wiring 30 is formed as a diffusion wiring by doping the front surface of the substrate 2 with a p-type impurity such as boron so as to have high concentration, for example, impurity concentration of about 10²⁰/cm³. The connection wiring 30 is doped with a p-type impurity at higher concentration than that of the piezoresistive element 4. As illustrated in FIG. 3, the connection wiring 30 is connected to the pad unit 20 via a metal contact 41 of tungsten or the like.

As illustrated in FIG. 1, the first connection wiring 30A includes a first portion 31 that connects the first sensor unit 10A and the first pad unit 20A, and a second portion 32 that connects the second sensor unit 10B and the first pad unit 20A. The second connection wiring 30B includes a first portion 33 that connects the second sensor unit 10B and the second pad unit 20B, and a second portion 34 that connects the third sensor unit 10C and the second pad unit 20B. The third connection wiring 30C includes a first portion 35 that connects the third sensor unit 10C and the third pad unit 20C, and a second portion 36 that connects the fourth sensor unit 10D and the third pad unit 20C. The fourth connection wiring 30D includes a first portion 37 that connects the fourth sensor unit 10D and the fourth pad unit 20D, and a second portion 38 that connects the first sensor unit 10A and the fourth pad unit 20D.

Each of the first portion 31 of the first connection wiring 30A, the second portion 34 of the second connection wiring 30B, the first portion 35 of the third connection wiring 30C, and the second portion 38 of the fourth connection wiring 30D includes a first straight portion 51 that is connected to the piezoresistive element 4 of the sensor unit 10 and extends linearly in the X direction, a second straight portion 52 that extends linearly in the Y direction from the first straight portion 51, and a third straight portion 53 that extends linearly in the X direction from the second straight portion 52 and is connected to the pad unit 20.

Each of the second portion 32 of the first connection wiring 30A, the first portion 33 of the second connection wiring 30B, the second portion 36 of the third connection wiring 30C, and the first portion 37 of the fourth connection wiring 30D includes a first straight portion 54 that is connected to the piezoresistive element 4 of the sensor unit 10 and extends linearly in the X direction, and a second straight portion 55 that extends linearly in the Y direction from the first straight portion 54 and is connected to the pad unit 20, and the first straight portion 54 is provided in a manner extending to the diaphragm 3 and the fixing portion 8.

As described above, the connection wiring 30 is formed as a diffusion wiring by doping the front surface of the substrate 2 with a p-type impurity at high concentration. The connection wiring 30 is a semiconductor wiring formed from a semiconductor material having a linear expansion coefficient equivalent to that of the substrate 2 which is a semiconductor substrate. In the present embodiment, the substrate 2 is a silicon substrate, and the connection wiring 30 is formed from silicon.

When pressure such as gas pressure acts from the side opposite to the cavity of the diaphragm 3, the MEMS sensor 1 formed in the above manner detects the pressure by detecting deflection of the diaphragm 3 due to a pressure difference acting on both sides of the diaphragm as a resistance value change of the piezoresistive element 4 of the sensor unit 10.

In the present embodiment, since the sensor unit 10, the pad unit 20, and the connection wiring 30 are formed on the semiconductor substrate 2, and the connection wiring 30 is a semiconductor wiring, linear expansion coefficients of the semiconductor substrate 2 and the connection wiring 30 can be made equal. Therefore, it is possible to suppress change in output of the sensor unit 10 due to generation of stress between the semiconductor substrate 2 and the connection wiring 30 due to a thermal history at the time of mounting and use, and it is possible to improve reliability of the sensor.

Next, a method of manufacturing the MEMS sensor 1 will be described.

In manufacture of the MEMS sensor 1, for example, the first substrate 6 and the second substrate 7, which are n-type silicon substrates doped with an n-type impurity such as phosphorus to be imparted with conductivity, are prepared. Then, the cavity 5 is formed on the first main surface 6a of the first substrate 6 by photolithography, etching, or the like.

Next, the first substrate 6 and the second substrate 7 are joined. Joining between the first substrate 6 and the second substrate 7 is performed by heating to predetermined temperature of, for example, 1000 degrees to 1200 degrees in a state where the second main surface 7b of the second substrate 7 is placed on the first main surface 6a of the first substrate 6 and predetermined pressurization is applied. By the above, the first substrate 6 and the second substrate 7 are directly joined, and the diaphragm 3 covering the cavity 5 and the fixing portion 8 fixed to the first substrate 6 are provided on the second substrate 7. Thickness of the diaphragm 3 is set to, for example, 3 μm to 30 μm.

Next, on the front surface of the substrate 2 which is the first main surface 7a of the second substrate 7, a portion where the piezoresistive element 4 is formed is selectively doped with a p-type impurity such as boron by ion implantation, and annealing treatment is performed. By the above, the piezoresistive element 4 as a diffusion resistor doped with a p-type impurity is formed on the front surface of the substrate 2.

Next, on the front surface of the substrate 2, a portion where the relay wiring 11 and the connection wiring 30 are formed is selectively doped with a p-type impurity such as boron by ion implantation and annealing treatment is performed. By the above, the relay wiring 11 and the connection wiring 30 are formed as diffusion wirings doped with a p-type impurity on the front surface of the substrate 2. The relay wiring 11 and the connection wiring 30 are doped with a p-type impurity at higher concentration than that of the piezoresistive element 4.

Next, the insulating film 40 such as a silicon oxide film is formed on the front surface of the substrate 2 by a CVD method. After formation of the insulating film 40, a contact hole is formed by photolithography and etching, and the contact hole is filled with metal such as tungsten so that the metal contact 41 is formed.

After the contact 41 is formed, an aluminum layer 42 is formed on the insulating film 40 by a PVD method, the aluminum layer 42 is patterned by photolithography and etching so that the pad unit 20 is formed, and the MEMS sensor 1 is manufactured.

In this way, in the MEMS sensor 1 in which the sensor unit 10, the pad unit 20, and the connection wiring 30 are formed on the semiconductor substrate 2, the connection wiring 30 is formed as a semiconductor wiring. By the above, linear expansion coefficients of the semiconductor substrate 2 and the connection wiring 30 can be made equal. Therefore, it is possible to suppress change in output of the sensor unit 10 due to generation of stress between the semiconductor substrate 2 and the connection wiring 30 due to a thermal history at the time of mounting and use, and it is possible to improve reliability of the sensor.

In the MEMS sensor 1, after the pad unit 20 is formed, a protective film of silicon nitride or the like may be formed on the insulating film 40 in a manner that the pad unit 20 is opened. Although the connection wiring 30 is connected to the pad unit 20 via the contact 41 provided on the insulating film 40, the connection wiring 30 can also be connected to the pad unit 20 without provision of the insulating film 40.

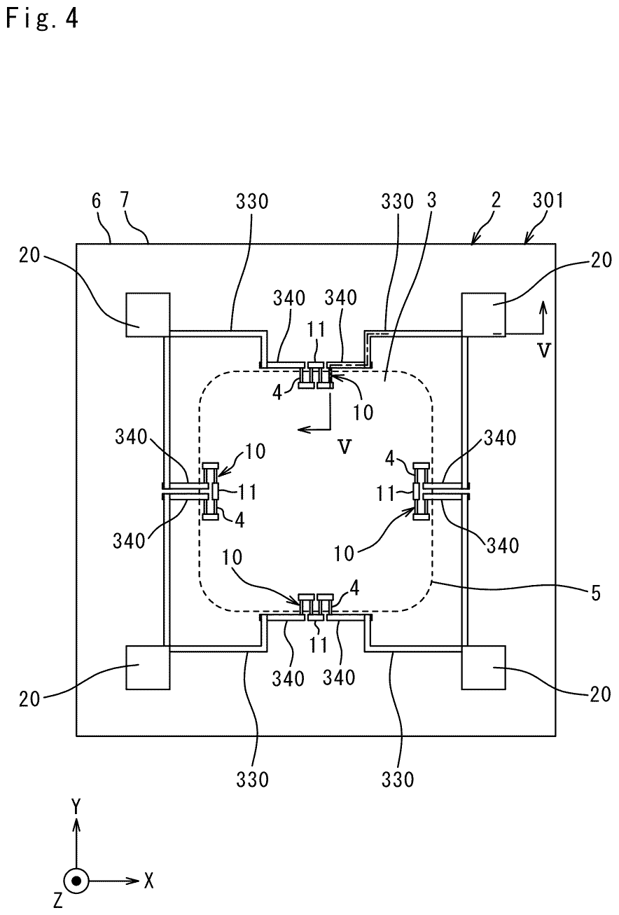

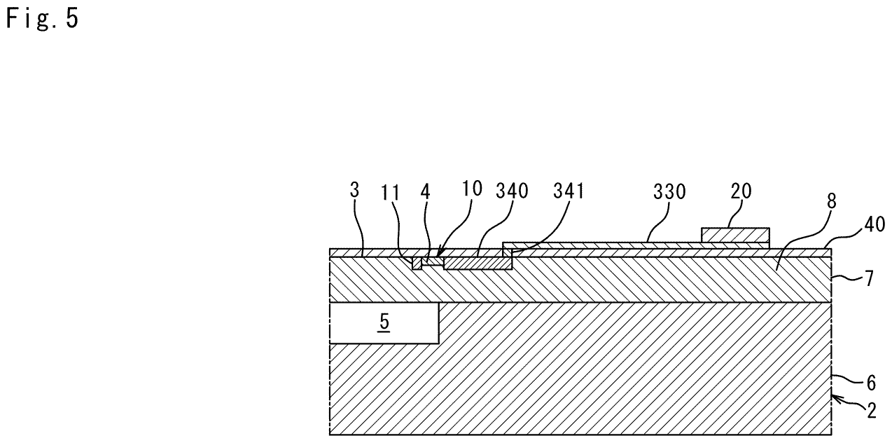

FIG. 4 is a plan view of a MEMS sensor in which a sensor unit and a pad unit are connected by a metal wiring. FIG. 5 is a cross-sectional view of the MEMS sensor taken along line V-V of FIG. 4. In a MEMS sensor 301 illustrated in FIGS. 4 and 5, a connection wiring 330 that connects the sensor unit 10 and the pad unit 20 and connects between the sensor units 10 is formed from a metal wiring of aluminum or the like.

As illustrated in FIG. 4, the connection wiring 330 is connected to the sensor unit 10 via a contact wiring 340. The contact wiring 340 is formed in a substantially rectangular shape in plan view, and is formed as a diffusion wiring by doping the front surface of the substrate 2 with a p-type impurity such as boron at high concentration.

As illustrated in FIG. 5, the connection wiring 330 is formed from a metal wiring of aluminum or the like so as to have predetermined width in plan view on the insulating film 40 formed on the front surface of the substrate 2. The connection wiring 330 has one end portion connected to the pad unit 20, and another end portion connected to the contact wiring 340 via a metal contact 341 of tungsten or the like formed on the insulating film 40.

As described above, in a case where a metal wiring of aluminum or the like is used as the connection wiring 330, due to a difference in linear expansion coefficient between the semiconductor substrate 2 and the metal wiring, stress is generated between the semiconductor substrate 2 and the connection wiring 330 due to a temperature change due to a thermal history at the time of mounting and at the time of use, and output of the sensor unit 10 is changed, and there is a possibility that reliability of the sensor is lowered.

In the present embodiment, in the MEMS sensor 1 in which the sensor unit 10, the pad unit 20, and the connection wiring 30 are formed on the semiconductor substrate 2, since the connection wiring 30 is a semiconductor wiring, linear expansion coefficients of the semiconductor substrate 2 and the connection wiring 30 can be made equal, and reliability of the sensor can be improved. It is possible to suppress change in output of the sensor unit due to generation of stress between the semiconductor substrate and the connection wiring due to a difference in linear expansion coefficient between the semiconductor substrate and the metal wiring as in the case of using the metal wiring, and it is possible to improve reliability of the sensor.

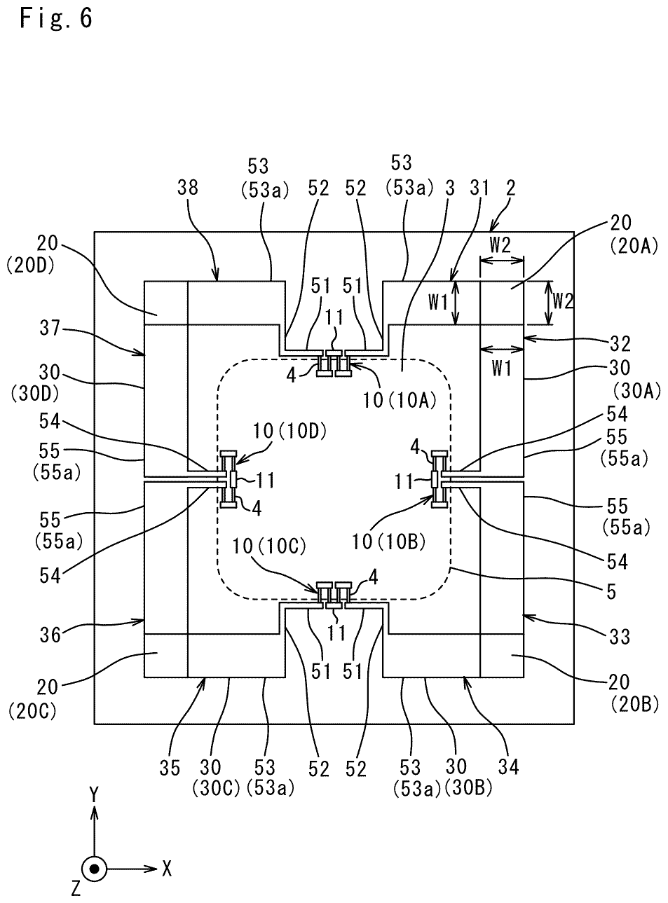

FIG. 6 is a plan view illustrating a variation of the MEMS sensor according to the first embodiment. As illustrated in FIG. 6, width W1 of the connection wiring 30 may have the same width W2 as the pad unit 20 in plan view. The third straight portion 53 of the first portion 31 of the first connection wiring 30A, the second portion 34 of the second connection wiring 30B, the first portion 35 of the third connection wiring 30C, and the second portion 38 of the fourth connection wiring 30D may each be formed as a third straight portion 53a having the same width as the pad unit 20, and the second straight portion 55 of the second portion 32 of the first connection wiring 30A, the first portion 33 of the second connection wiring 30B, the second portion 36 of the third connection wiring 30C, and the first portion 37 of the fourth connection wiring 30D may each be formed as a second straight portion 55a having the same width as the pad unit 20.

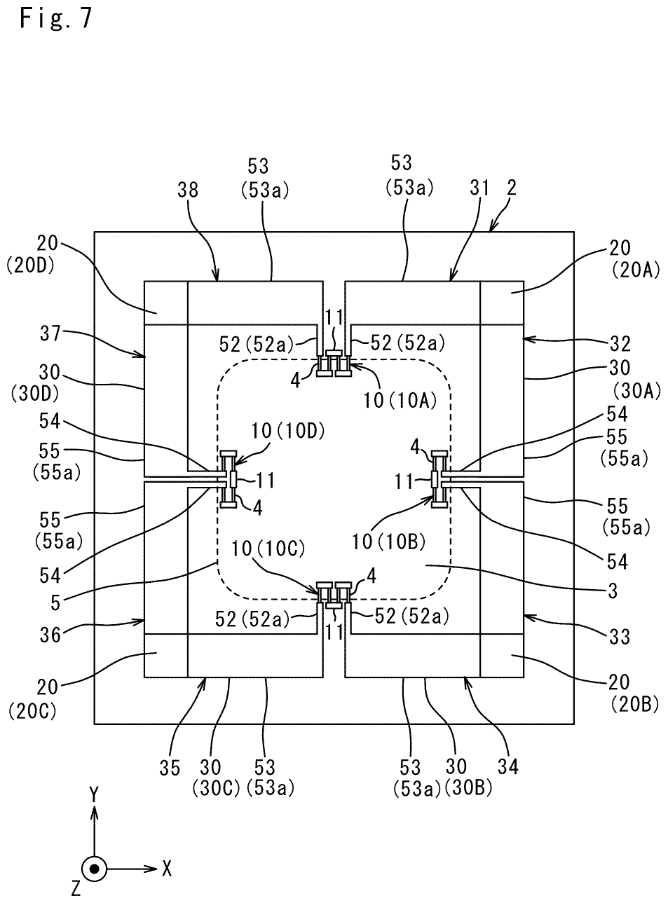

FIG. 7 is a plan view illustrating another variation of the MEMS sensor according to the first embodiment. As illustrated in FIG. 7, for each of the first portion 31 of the first connection wiring 30A, the second portion 34 of the second connection wiring 30B, the first portion 35 of the third connection wiring 30C, and the second portion 38 of the fourth connection wiring 30D, the second straight portion 52 may be formed as a second straight portion 52a that is connected to the piezoresistive element 4 of the sensor unit 10 and linearly extends in the Y direction, and the third straight portion 53 may be formed as a third straight portion 53a that linearly extends in the X direction from the second straight portion 52a and is connected to the pad unit 20.

In the MEMS sensor 1 illustrated in FIG. 1, width of the connection wiring 30 is formed to be smaller than width of the pad unit 20 in plan view. However, as illustrated in FIGS. 6 and 7, the connection wiring 30 may have the same width as the width of the pad unit 20 in plan view, or may have width larger than the width of the pad unit 20 in plan view. In a case where width of the connection wiring 30 is the same as the width of the pad unit 20 or larger than the width of the pad unit 20, the width can be set to, for example, 50 μm to 150 μm. Further, each of a plurality of the connection wirings 30, that is, the connection wirings 30A, 30B, 30C, and 30D can be formed to have the same electric resistance value.

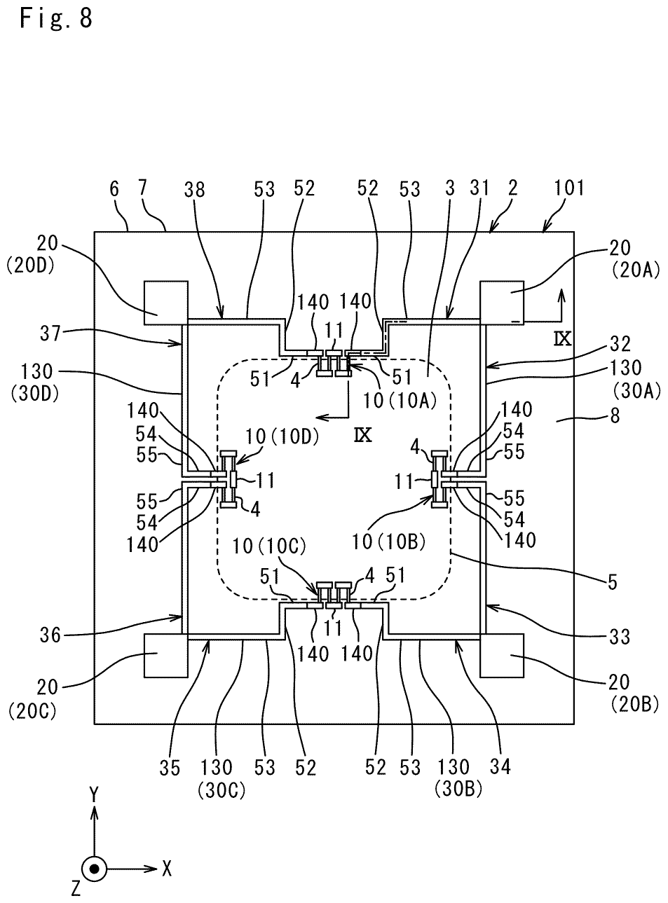

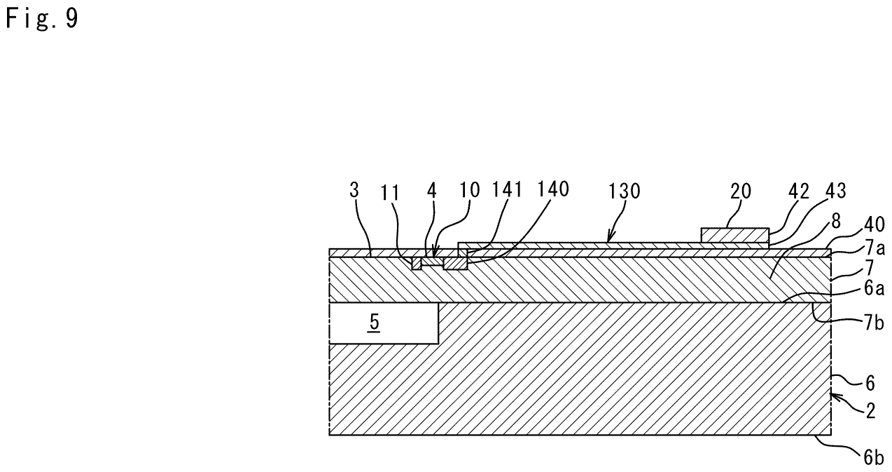

FIG. 8 is a plan view of the MEMS sensor according to a second embodiment of the present disclosure. FIG. 9 is a cross-sectional view of the MEMS sensor taken along line IX-IX in FIG. 8. A MEMS sensor 101 according to the second embodiment is different from the MEMS sensor 1 according to the first embodiment in connection wiring, and description of the same configuration will be omitted.

As illustrated in FIG. 8, also in the MEMS sensor 101, a connection wiring 130 that connects the sensor unit 10 and the pad unit 20 and connects between the sensor units 10 includes the first connection wiring 30A, the second connection wiring 30B, the third connection wiring 30C, and the fourth connection wiring 30D similarly to the connection wiring 30.

Also in the MEMS sensor 101, the first connection wiring 30A, the second connection wiring 30B, the third connection wiring 30C, and the fourth connection wiring 30D have the first portions 31,33,35, and 37 and the second portions 32,34,36, and 38, respectively. Each of the first portion 31 of the first connection wiring 30A, the second portion 34 of the second connection wiring 30B, the first portion 35 of the third connection wiring 30C, and the second portion 38 of the fourth connection wiring 30D has the first straight portion 51, the second straight portion 52, and the third straight portion 53. Each of the second portion 32 of the first connection wiring 30A, the first portion 33 of the second connection wiring 30B, the second portion 36 of the third connection wiring 30C, and the first portion 37 of the fourth connection wiring 30D has the first straight portion 54 and the second straight portion 55.

In the present embodiment, the connection wiring 130 is formed as a polycrystalline silicon wiring formed from polycrystalline silicon by a CVD method using a silicon material. As the polycrystalline silicon, p-type polycrystalline silicon containing a p-type impurity such as boron is used. As illustrated in FIG. 9, the connection wiring 130 is formed on the insulating film 40 formed on the front surface of the substrate 2. The first connection wiring 30A to fourth connection wiring 30D are connected to first pad unit 20A to fourth pad unit 20D, respectively. As the connection wiring 130, a polycrystalline silicon wiring formed from n-type polycrystalline silicon containing an n-type impurity such as phosphorus may be used.

Each of the first connection wiring 30A to the fourth connection wiring 30D is connected to the sensor unit 10 via a contact wiring 140. As illustrated in FIG. 8, the contact wiring 140 is formed in a substantially rectangular shape in plan view, and is formed as a diffusion wiring by doping the front surface of the substrate 2 with a p-type impurity such as boron at high concentration.

Each of the first connection wiring 30A to the fourth connection wiring 30D is connected to the contact wiring 140 via a metal contact 141 of tungsten or the like in which the first straight portions 51 and 54 are formed on the insulating film 40.

When the MEMS sensor 101 is manufactured, for example, after the piezoresistive element 4 as a diffusion resistor doped with a p-type impurity is formed on the front surface of the substrate 2, a portion where the relay wiring 11 and the contact wiring 140 are formed on the front surface of the substrate 2 is selectively doped with a p-type impurity such as boron by ion implantation and annealing treatment is performed. By the above, the relay wiring 11 and the contact wiring 140 as diffusion wirings doped with a p-type impurity are formed on the front surface of the substrate 2. The relay wiring 11 and the contact wiring 140 are doped with a p-type impurity at higher concentration than the piezoresistive element 4.

Next, the insulating film 40 such as a silicon oxide film is formed on the front surface of the substrate 2 by a CVD method, a contact hole is formed by photolithography and etching, and the contact hole is filled with metal such as tungsten to form the metal contact 141.

After the contact 141 is formed, a polycrystalline silicon layer 43 is formed on the insulating film 40 by a CVD method, and the polycrystalline silicon layer 43 is patterned by photolithography and etching to form the connection wiring 130. After formation of the connection wiring 130, the aluminum layer 42 is formed on the connection wiring 130 by a PVD method, the aluminum layer 42 is patterned by photolithography and etching to form the pad unit 20, and the MEMS sensor 1 is manufactured.

When pressure such as gas pressure acts from the side opposite to the cavity of the diaphragm 3, the MEMS sensor 101 formed in this manner also detects the pressure by detecting deflection of the diaphragm 3 due to a pressure difference acting on both sides of the diaphragm as a resistance value change of the piezoresistive element 4 of the sensor unit 10.

In the MEMS sensor 101, the connection wiring 130 is formed as a polycrystalline silicon wiring formed from polycrystalline silicon, and is a semiconductor wiring formed from a semiconductor material having a linear expansion coefficient equivalent to that of the semiconductor substrate 2. Also in the present embodiment, the substrate 2 is a silicon substrate, and the connection wiring 130 is formed from silicon.

Also in the present embodiment, in the MEMS sensor 101 in which the sensor unit 10, the pad unit 20, and the connection wiring 130 are formed on the semiconductor substrate 2, since the connection wiring 130 is a semiconductor wiring, linear expansion coefficients of the semiconductor substrate 2 and the connection wiring 130 can be made equal. Therefore, it is possible to suppress change in output of the sensor unit due to generation of stress between the semiconductor substrate and the connection wiring due to a thermal history at the time of mounting and use, and it is possible to improve reliability of the sensor.

In the present embodiment, the connection wiring 130 is a polycrystalline silicon wiring formed from polycrystalline silicon. By the above, since the polycrystalline silicon wiring is formed from the same material as the semiconductor substrate 2, it is possible to suppress change in output of the sensor unit 10 due to generation of thermal stress between the semiconductor substrate 2 and the connection wiring 130.

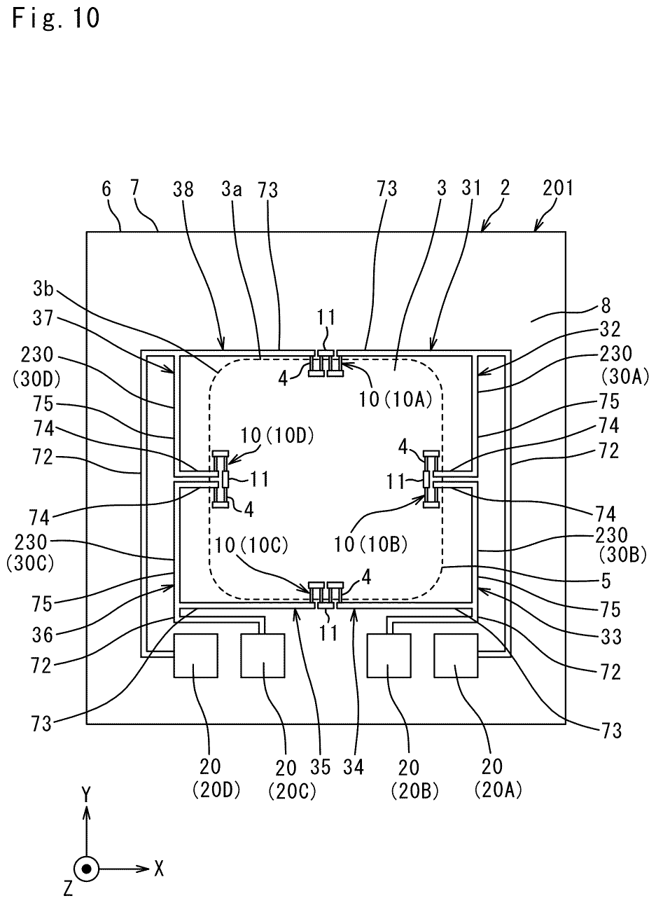

FIG. 10 is a plan view of the MEMS sensor according to a third embodiment of the present disclosure. A MEMS sensor 201 according to the third embodiment is different from the MEMS sensor 1 according to the first embodiment in a connection wiring and a pad unit, and description of the same configuration will be omitted.

As illustrated in FIG. 10, in the present embodiment, a plurality of the pad units 20 are arranged on another side in the Y direction of the diaphragm 3 in the fixing portion 8 of the substrate 2 so as to be separated from each other in the X direction. The first pad unit 20A, the second pad unit 20B, the third pad unit 20C, and the fourth pad unit 20D are arranged in this order from one side in the X direction.

Also in the MEMS sensor 201, similarly to the connection wiring 30, a plurality of connection wirings 230 connecting the sensor unit 10 and the pad unit 20 and connecting between the sensor units 10 include the first connection wiring 30A that connects the first sensor unit 10A and the second sensor unit 10B and is connected to the first pad unit 20A, the second connection wiring 30B that connects the second sensor unit 10B and the third sensor unit 10C and is connected to the second pad unit 20B, the third connection wiring 30C that connects the third sensor unit 10C and the fourth sensor unit 10D and is connected to the third pad unit 20C, and the fourth connection wiring 30D that connects the fourth sensor unit 10D and the first sensor unit 10A and is connected to the fourth pad unit 20D.

The connection wiring 230 forms a bridge circuit by bridge connecting the piezoresistive elements 4 of the first sensor unit 10A to the fourth sensor unit 10D. The connection wiring 230 has predetermined thickness in a thickness direction of the substrate 2 and is formed to have predetermined width smaller than width of the pad unit 20 in plan view. The connection wiring 230 is formed as a diffusion wiring by doping the front surface of the substrate 2 with a p-type impurity such as boron at high concentration. The connection wiring 230 is doped with a p-type impurity at higher concentration than that of the piezoresistive element 4. The connection wiring 230 is connected to the pad unit 20 via a metal contact of tungsten or the like.

In the present embodiment, the first connection wiring 30A includes the first portion 31 connecting the first sensor unit 10A and the first pad unit 20A and the second portion 32 connecting the second sensor unit 10B and the first pad unit 20A, and the pad unit side of the first portion 31 and the second portion 32 is a common portion 72. The second connection wiring 30B includes the first portion 33 connecting the second sensor unit 10B and the second pad unit 20B and the second portion 34 connecting the third sensor unit 10C and the second pad unit 20B, and the pad unit side of the first portion 33 and the second portion 34 is the common portion 72.

The third connection wiring 30C includes the first portion 35 connecting the third sensor unit 10C and the third pad unit 20C and the second portion 36 connecting the fourth sensor unit 10D and the third pad unit 20C, and the pad unit side of the first portion 35 and the second portion 36 is the common portion 72. The fourth connection wiring 30D includes the first portion 37 connecting the fourth sensor unit 10D and the fourth pad unit 20D and the second portion 38 connecting the first sensor unit 10A and the fourth pad unit 20D, and the pad unit side of the first portion 37 and the second portion 38 is the common portion 72.

Each of the first portion 31 of the first connection wiring 30A, the second portion 34 of the second connection wiring 30B, the first portion 35 of the third connection wiring 30C, and the second portion 38 of the fourth connection wiring 30D has a first straight portion 73 in which the sensor unit side is connected to the piezoresistive element 4 of the sensor unit 10, extends linearly in the X direction, and is connected to the common portion 72.

Each of the second portion 32 of the first connection wiring 30A, the first portion 33 of the second connection wiring 30B, the second portion 36 of the third connection wiring 30C, and the first portion 37 of the fourth connection wiring 30D has a first straight portion 74 in which the sensor unit side is connected to the piezoresistive element 4 of the sensor unit 10 and linearly extends in the X direction, and a second straight portion 75 that linearly extends in the Y direction from the first straight portion 74 and is connected to the common portion 72. The first straight portion 74 is provided to extend to the diaphragm 3 and the fixing portion 8.

As described above, the connection wiring 230 is formed as a diffusion wiring by doping the front surface of the substrate 2 with a p-type impurity at high concentration. The connection wiring 230 is a semiconductor wiring formed from a semiconductor material having a linear expansion coefficient equivalent to that of the substrate 2 which is a semiconductor substrate.

Also in the present embodiment, linear expansion coefficients of the semiconductor substrate 2 and the connection wiring 230 can be made equal. Therefore, it is possible to suppress change in output of the sensor unit 10 due to generation of stress between the semiconductor substrate 2 and the connection wiring 230 due to a thermal history at the time of mounting and use, and it is possible to improve reliability of the sensor.

Also in the MEMS sensor 201 according to the third embodiment, as in a variation of the MEMS sensor 1 according to the first embodiment, the connection wiring 230 may have the same width as width of the pad unit 20 in plan view, or may have width larger than width of the pad unit 20 in plan view. Further, each of a plurality of the connection wirings 230 can be formed to have an equivalent electric resistance value.

Also in the MEMS sensor 201 according to the third embodiment, similarly to the MEMS sensor 101 according to the second embodiment, each of the first connection wiring 30A to the fourth connection wiring 30D can be formed as a polycrystalline silicon wiring formed from polycrystalline silicon by a CVD method using silicon.

In such a case, each of the first connection wiring 30A to the fourth connection wiring 30D is connected to the sensor unit 10 via the contact wiring 140, and the contact wiring 140 is formed as a diffusion wiring by doping the front surface of the substrate 2 with a p-type impurity such as boron at high concentration. In each of the first connection wiring 30A to the fourth connection wiring 30D, the first straight portions 73 and 74 are connected to the contact wiring 140 via the metal contact 141 of tungsten or the like provided in the insulating film 40 formed on the front surface of the substrate 2.

In the MEMS sensors 1, 101, and 201, an n-type silicon substrate is used as the silicon substrate 2, the piezoresistive element 4 of the sensor unit 10 is formed as a p-type diffusion resistor, and the relay wiring 11, the contact wiring 140, and the connection wiring 230 are formed as a p-type diffusion wiring. However, a p-type silicon substrate may be used as the silicon substrate 2, the piezoresistive element 4 of the sensor unit 10 may be formed as an n-type diffusion resistor, and the relay wiring 11, the contact wiring 140, and the connection wiring 230 may be formed as an n-type diffusion wiring.

In the above-described embodiment, the sensor unit 10 includes four of the piezoresistive elements 4, but the present disclosure is not limited to this, and may include one or two or more of the piezoresistive elements 4. In the substrate 2, the cavity 5 and the diaphragm 3 are formed in the substrate 2 by joining the first substrate 6 and the second substrate 7, but the cavity 5 and the diaphragm 3 may be formed in one of the substrate 2.

Further, although the cavity 5 formed in the substrate 2 is formed in a sealed manner, the cavity 5 may be connected to a predetermined pressure chamber or the like. The MEMS sensor 1 is a pressure sensor, but is also applicable to other sensors such as an atmospheric pressure sensor.

In the MEMS sensor in which the sensor unit 10, the pad unit 20, and the connection wiring 30 are formed on the semiconductor substrate 2, the connection wiring 30 can be a semiconductor wiring formed from a semiconductor material having a linear expansion coefficient equivalent to that of the semiconductor substrate 2, and can be a diffusion wiring formed by introducing an impurity into the semiconductor substrate 2 or a polycrystalline silicon wiring formed from polycrystalline silicon.

As described above, in the present embodiment, in the MEMS sensors 1, 101, and 201 including the sensor unit 10, the pad unit 20, and the connection wirings 30, 130, and 230 formed on the semiconductor substrate 2, the connection wirings 30, 130, and 230 are a semiconductor wiring. By the above, linear expansion coefficients of the semiconductor substrate 2 and the connection wirings 30, 130, 230 can be made equal. Therefore, it is possible to suppress change in output of the sensor unit 10 due to generation of stress between the semiconductor substrate and the connection wiring due to a thermal history at the time of mounting and use, and it is possible to improve reliability of the sensor. It is possible to suppress change in output of the sensor unit due to generation of stress between the semiconductor substrate and the wiring due to a difference in linear expansion coefficient between the semiconductor substrate and the metal wiring as in a case of using the metal wiring, and it is possible to improve reliability of the sensor unit.

Further, the connection wirings 30, 130, and 230 are formed from a semiconductor material having a linear expansion coefficient equivalent to that of the semiconductor substrate 2. By the above, it is possible to suppress generation of stress between the semiconductor substrate and the connection wiring due to a thermal history, and it is possible to improve reliability of the sensor as compared with a case where the connection wiring is formed from a metal material having a linear expansion coefficient different from that of the semiconductor substrate.

Further, the semiconductor substrate 2 is a silicon substrate, and the connection wirings 30, 130, and 230 are formed from silicon. By the above, since the semiconductor substrate 2 and the connection wirings 30, 130, and 230 are formed from silicon which is the same material, generation of thermal stress between the semiconductor substrate and the connection wiring can be suppressed.

Further, the connection wirings 30, 130, and 230 can be a diffusion wiring formed by introducing an impurity into the semiconductor substrate 2. By the above, since the diffusion wiring is formed from the same material as the semiconductor substrate 2, it is possible to suppress change in output of the sensor unit due to generation of thermal stress between the semiconductor substrate and the connection wiring.

Further, the connection wiring 130 may be a polycrystalline silicon wiring formed from polycrystalline silicon. By the above, since the polycrystalline silicon wiring is formed from the same material as the semiconductor substrate 2, it is possible to suppress change in output of the sensor unit 10 due to generation of thermal stress between the semiconductor substrate and the connection wiring.

Further, the connection wiring 30 may have the same width as the pad unit 20 in plan view. By the above, as compared with a case where the connection wiring 30 has width smaller than that of the pad unit 20 in plan view, width of the connection wiring 30 is made large to reduce an electric resistance value of the connection wiring 30, and accuracy of the sensor can be improved.

Further, a plurality of the sensor units 10, a plurality of the pad units 20, and a plurality of the connection wirings 30 may be formed on the semiconductor substrate 2, and a plurality of the connection wirings 30 may be formed so as to have equivalent electric resistance values. By the above, accuracy of the sensor can be improved as compared with a case where a plurality of the connection wirings 30 are not formed to have equivalent electric resistance values.

Further, the semiconductor substrate 2 includes the diaphragm 3, and the sensor unit 10 is provided on the diaphragm 3. By the above, since the sensor unit 10 can be changed in accordance with deformation of the diaphragm 3, deformation of the diaphragm 3 can be detected by the sensor unit 10.

Further, the diaphragm 3 is formed in a quadrangular shape in plan view, and the sensor unit 10 includes the piezoresistive element 4 formed on each of the side portions 3a of the diaphragm 3. By the above, a resistance value of the piezoresistive element 4 can be changed according to deformation of the diaphragm 3 by the piezoresistive element 4 formed on each of the side portions 3a of the diaphragm 3, and deformation of the diaphragm 3 can be detected by the piezoresistive element 4.

Further, a plurality of the connection wirings 30A, 30B, 30C, and 30D form a bridge circuit including the piezoresistive element 4 formed on each of the side portions 3a of the diaphragm 3. By the above, since the connection wirings 30A, 30B, 30C, and 30D form a bridge circuit including four of the piezoresistive elements 4, deformation of the diaphragm 3 can be detected by the sensor unit 10 with high sensitivity.

Further, the cavity 5 formed in the semiconductor substrate 2 is sealed by the diaphragm 3. By the above, it is possible to accurately detect pressure applied only to the side opposite to the cavity of the diaphragm 3 with reference to pressure in the cavity 5 as deformation of the diaphragm 3 by the sensor unit 10.

Further, the semiconductor substrate 2 includes the first semiconductor substrate 6 having the cavity 5 and the second semiconductor substrate 7 having the diaphragm 3 covering the cavity 5 and joined to the first semiconductor substrate 6, and the sensor unit 10 is provided on the diaphragm 3. By the above, it is possible to join the first semiconductor substrate 6 and the second semiconductor substrate 7 and seal the cavity 5 with the diaphragm 3, and accurately detect pressure applied only to the side opposite to the cavity of the diaphragm 3 with reference to pressure in the cavity 5 as deformation of the diaphragm 3 by the sensor unit 10.

The MEMS sensors 1, 101, and 201 are pressure sensors. In the MEMS sensors 1, 101, and 201 that are pressure sensors, it is possible to suppress change in output of the sensor unit due to generation of stress between the semiconductor substrate and the connection wiring due to a thermal history at the time of mounting or use, and it is possible to improve reliability of the sensor.

The present disclosure is not limited to the illustrated embodiment, and various improvements and design changes can be made without departing from the gist of the present disclosure.

### Clause 1

A MEMS sensor comprising:
a semiconductor substrate;
a sensor unit formed on the semiconductor substrate;
a pad unit formed on the semiconductor substrate; and
a connection wiring formed on the semiconductor substrate and connecting the sensor unit and the pad unit, wherein
the connection wiring is a semiconductor wiring formed from a semiconductor material.

### Clause 2

The MEMS sensor according to clause 1, wherein
the connection wiring is formed from a semiconductor material having a linear expansion coefficient equivalent to that of the semiconductor substrate.

### Clause 3

The MEMS sensor according to clause 1 or 2, wherein
the semiconductor substrate is a silicon substrate, and
the connection wiring is formed from silicon.

### Clause 4

The MEMS sensor according to any one of clauses 1 to 3, wherein
the connection wiring is a diffusion wiring formed by introducing an impurity into the semiconductor substrate.

### Clause 5

The MEMS sensor according to any one of clauses 1 to 3, wherein
the connection wiring is a polycrystalline silicon wiring formed from polycrystalline silicon.

### Clause 6

The MEMS sensor according to any one of clauses 1 to 5, wherein
the connection wiring has same width as the pad unit in plan view.

### Clause 7

The MEMS sensor according to any one of clauses 1 to 6, wherein
a plurality of the sensor units and a plurality of the pad units are formed on the semiconductor substrate,
a plurality of the connection wirings connecting the sensor unit and the pad unit are formed on the semiconductor substrate, and
the plurality of connection wirings are formed to have equivalent electric resistance values.

### Clause 8

The MEMS sensor according to any one of clauses 1 to 7, wherein
the semiconductor substrate includes a diaphragm, and
the sensor unit is provided on the diaphragm.

### Clause 9

The MEMS sensor according to clause 8, wherein
the diaphragm is formed in a quadrangular shape in plan view, and
the sensor unit includes a piezoresistive element formed on each side portion of the diaphragm.

### Clause 10

The MEMS sensor according to clause 9, wherein
a plurality of the connection wirings connecting the sensor unit and the pad unit are formed on the semiconductor substrate, and
the plurality of connection wirings form a bridge circuit including a piezoresistive element formed on each side portion of the diaphragm.

### Clause 11

The MEMS sensor according to any one of clauses 8 to 10, wherein
a cavity is formed in the semiconductor substrate, and
the cavity is sealed by the diaphragm.

### Clause 12

The MEMS sensor according to any one of clauses 1 to 11, wherein
the semiconductor substrate includes a first semiconductor substrate having a cavity and a second semiconductor substrate having a diaphragm covering the cavity and joined to the first semiconductor substrate, and
the sensor unit is provided on the diaphragm.

### Clause 13

The MEMS sensor according to any one of clauses 1 to 12, wherein
the MEMS sensor is a pressure sensor.

### EXPLANATION OF REFERENCES

1, 101, 201 MEMS sensor
2 substrate
3 diaphragm
4 piezoresistive element
5 cavity
6 first substrate
7 second substrate
10 sensor unit
20 pad unit
30, 130, 230 connection wiring

What is claimed is:

1. A MEMS sensor comprising:
a semiconductor substrate;
a sensor unit formed on the semiconductor substrate;
a pad unit formed on the semiconductor substrate; and
a connection wiring formed on the semiconductor substrate and connecting the sensor unit and the pad unit, wherein
the connection wiring is a semiconductor wiring formed from a semiconductor material.

2. The MEMS sensor according to claim 1, wherein
the connection wiring is formed from a semiconductor material having a linear expansion coefficient equivalent to that of the semiconductor substrate.

3. The MEMS sensor according to claim 1, wherein
the semiconductor substrate is a silicon substrate, and
the connection wiring is formed from silicon.

4. The MEMS sensor according to claim 1, wherein
the connection wiring is a diffusion wiring formed by introducing an impurity into the semiconductor substrate.

5. The MEMS sensor according to claim 1, wherein
the connection wiring is a polycrystalline silicon wiring formed from polycrystalline silicon.

6. The MEMS sensor according to claim 1, wherein
the connection wiring has same width as the pad unit in plan view.

7. The MEMS sensor according to claim 1, wherein
a plurality of the sensor units and a plurality of the pad units are formed on the semiconductor substrate,
a plurality of the connection wirings connecting the sensor unit and the pad unit are formed on the semiconductor substrate, and
the plurality of connection wirings are formed to have equivalent electric resistance values.

8. The MEMS sensor according to claim 1, wherein
the semiconductor substrate includes a diaphragm, and
the sensor unit is provided on the diaphragm.

9. The MEMS sensor according to claim 8, wherein
the diaphragm is formed in a quadrangular shape in plan view, and
the sensor unit includes a piezoresistive element formed on each side portion of the diaphragm.

10. The MEMS sensor according to claim 9, wherein
a plurality of the connection wirings connecting the sensor unit and the pad unit are formed on the semiconductor substrate, and
the plurality of connection wirings form a bridge circuit including a piezoresistive element formed on each side portion of the diaphragm.

11. The MEMS sensor according to claim 8, wherein
a cavity is formed in the semiconductor substrate, and
the cavity is sealed by the diaphragm.

12. The MEMS sensor according to claim 1, wherein
the semiconductor substrate includes a first semiconductor substrate having a cavity and a second semiconductor substrate having a diaphragm covering the cavity and joined to the first semiconductor substrate, and
the sensor unit is provided on the diaphragm.

13. The MEMS sensor according to claim 1, wherein
the MEMS sensor is a pressure sensor.
